(19) United States
(12) Patent Application Publication
(10) Pub. No.: US 2025/0287494 A1
(43) Pub. Date: Sep. 11, 2025

(54) ELECTRICAL CIRCUIT AND IMAGE FORMING APPARATUS

(71) Applicant: CANON KABUSHIKI KAISHA, Tokyo (JP)

(72) Inventor: YOSHIAKI HARA, Chiba (JP)

(21) Appl. No.: 19/070,968

(22) Filed: Mar. 5, 2025

(30) Foreign Application Priority Data
Mar. 7, 2024 (JP) 2024-034645

(51) Int. Cl. H05K 1/02

(52) U.S. Cl. CPC H05K 1/0203; H05K 1/0216; H05K 2201/064; H05K 2201/0707; H05K 2201/10196; H05K 2201/10371; H05K 2201/10409

(57) ABSTRACT

An electrical circuit includes an electronic component, a circuit board having a first surface on which the electronic component is arranged, and a cover provided on the first surface and configured to form an accommodating space where the electronic component is accommodated, the cover including a first part and a second part, wherein the first part of the cover is in contact with the first surface of the circuit board, wherein an opening is formed between the second part of the cover and the first surface of the circuit board, wherein a path of an air stream is formed, the path communicating from an outside of the cover to the electronic component in the accommodating space through the opening, and wherein the cover includes a shielding member arranged between the opening and the electronic component in the accommodating space.

### BACKGROUND

### Field

The present disclosure relates to an electrical circuit including a circuit board having an electronic component mounted thereon, and to an image forming apparatus including such an electrical circuit.

### Description of the Related Art

In order to control electrical components such as various motors, various sensors, and switches, an image forming apparatus includes a power supply board, a high-voltage board, a control board, and the like having electronic components mounted thereon. In the image forming apparatus, a protection circuit board having a protection circuit formed thereon is provided in order to electrically protect the electronic components mounted on those circuit boards from an excessive voltage or current. Those circuit boards are mainly arranged in a back space of a main body of the image forming apparatus.

Each circuit board is removed or replaced at the time of failure or for maintenance. Further, there is a demand for arrangement of the circuit board in a space-saving manner in order to downsize the image forming apparatus. Accordingly, an operator is required to be careful not to damage the electronic component mounted on the circuit board at the time of performing assembly or component replacement of the image forming apparatus. In Japanese Patent Application Laid-open No. 2018-110154, there has been proposed an electrical circuit in which an electronic component is covered with a cover, and further a circuit board itself is covered with a box-shaped component.

In a case where the circuit board itself is covered with the box-shaped component, the cost of components is increased, and a space required at the time of mounting the circuit board to the image forming apparatus is also increased. Further, in a case where the electronic component is covered with the cover, the electronic component becomes hot without being cooled with surrounding air at the time of operation. This state causes malfunction and reduction in component life of the electronic component.

### SUMMARY

According to some embodiments, an electrical circuit includes an electronic component, a circuit board having a first surface on which the electronic component is arranged, and a cover provided on the first surface and configured to form an accommodating space where the electronic component is accommodated, the cover including a first part and a second part, wherein the first part of the cover is in contact with the first surface of the circuit board, wherein an opening is formed between the second part of the cover and the first surface of the circuit board, wherein a path of an air stream is formed, the path communicating from an outside of the cover to the electronic component in the accommodating space through the opening, and wherein the cover includes a shielding member arranged between the opening and the electronic component in the accommodating space.

An image forming apparatus according to another embodiment of the present disclosure includes a module configured to perform an operation relating to image formation, and an electrical circuit configured to be used in the operation of the module, wherein the electrical circuit includes an electronic component, a circuit board having a first surface on which the electronic component is arranged, and a cover provided on the first surface and configured to form an accommodating space where the electronic component is accommodated, the cover including a first part and a second part, wherein the first part of the cover is in contact with the first surface of the circuit board, wherein an opening is formed between the second part of the cover and the first surface of the circuit board, wherein a path of an air stream is formed, the path communicating from an outside of the cover to the electronic component in the accommodating space through the opening, and wherein the cover includes a shielding member arranged between the opening and the electronic component in the accommodating space.

Further features of the present disclosure will become apparent from the following description of exemplary embodiments (with reference to the attached drawings).

### BRIEF DESCRIPTION OF THE DRAWINGS

FIG. 1 is a configuration view for illustrating an ink jet recording apparatus.

FIG. 2 is an explanatory view for illustrating an arrangement of electrical circuits.

FIG. 3 is an explanatory view for illustrating a configuration of a protection circuit board.

FIG. 4 is an explanatory view for illustrating the configuration of the protection circuit board in a state in which an element cover is mounted.

FIG. 5 is an explanatory view for illustrating the configuration of the protection circuit board in the state in which the element cover is mounted.

FIG. 6A and FIG. 6B are explanatory views for illustrating a configuration of the element cover.

FIG. 7 is an explanatory view for illustrating a state in which the protection circuit board is mounted to a cooling module.

FIG. 8 is an explanatory view for illustrating another example of a method of fixing the element cover.

FIG. 9A and FIG. 9B are explanatory views for illustrating another example of the method of fixing the element cover.

### DESCRIPTION OF THE EMBODIMENTS

Now, referring to the accompanying drawings, description is given of various exemplary embodiments, features, and aspects of the present disclosure.

The present disclosure advantageously provides an electrical circuit with which, while a life of an electronic component mounted on a circuit board is kept long, the electronic component can be protected from being damaged.

FIG. 1 is a configuration view for illustrating an ink-jet recording apparatus which is an image forming apparatus according to this embodiment. The ink-jet recording apparatus 100 according to this embodiment is a sheet-fed image forming apparatus that forms an ink image on a sheet using two liquids, specifically, a reaction liquid and an ink to produce a printed product.

The ink-jet recording apparatus 100 includes a sheet feeding module 1000, a printing module 2000, a drying module 3000, a fixing module 4000, a cooling module 5000, a reversing module 6000, and a sheet discharging and stacking module 7000. A cut paper-like sheet on which an image is to be printed is fed from the sheet feeding module 1000, subjected to predetermined processing relating to image formation by each module, and discharged to the sheet discharging and stacking module 7000.

The sheet feeding module 1000 includes a plurality of sheet storage portions 1100a to 1100c (three sheet storage portions in this embodiment). Each of the sheet storage portions 1100a to 1100c can store sheets therein. Each of the sheet storage portions 1100a to 1100c is configured to be capable of being drawn toward a front side of the apparatus, and sheets are stored in each sheet storage portion after the sheet storage portion is drawn toward the front side of the apparatus. The sheet feeding module 1000 feeds sheets one by one to the printing module 2000. Thus, each of the sheet storage portions 1100a to 1100c includes a separation belt and conveyance rollers. The number of the sheet storage portions 1100a to 1100c is an example, and may be one, two, or four or more.

The printing module 2000 forms an image on a sheet fed from the sheet feeding module 1000. The printing module 2000 includes a pre-image-forming registration correction unit (not shown), a print belt unit 2200, and a recording unit 2300. The pre-image-forming registration correction unit corrects an inclination and a position of the sheet fed from the sheet feeding module 1000, and conveys the sheet to the print belt unit 2200.

The print belt unit 2200 and the recording unit 2300 are arranged on a downstream side of the pre-image-forming registration correction unit in a sheet conveying direction so as to be opposed to each other across a sheet conveyance path. The print belt unit 2200 conveys, through suction, a sheet to be conveyed from the pre-image-forming registration correction unit. The recording unit 2300 is a sheet processing unit that performs recording processing (printing) from above by a recording head to form an image on the sheet conveyed by the print belt unit 2200. The recording head performs printing by ejecting the ink onto the sheet. The sheet is conveyed through suction by the print belt unit 2200, and thus a constant clearance between the recording head and the sheet is maintained.

A plurality of recording heads is arranged along the sheet conveying direction. The recording heads in this embodiment are five line-type recording heads corresponding to four colors of Y (yellow), M (magenta), C (cyan), and K (black), and the reaction liquid. The number of colors and the number of recording heads are not limited to five. As the ink-jet system, a system using a heat generating element, a piezoelectric element, an electrostatic element, or a MEMS element can be adopted. The ink of each color is supplied to the recording head from an ink tank (not shown) through an ink tube.

The sheet printed in the recording unit 2300 is conveyed by the print belt unit 2200. An in-line scanner (not shown) is arranged on a downstream side of the recording unit 2300 in the conveying direction. The in-line scanner is used in order to detect misalignment and color density of the image formed on the sheet and to correct an image to be printed.

The drying module 3000 dries the sheet on which the image has been formed by the printing module 2000. The drying module 3000 dries the sheet to reduce a liquid component contained in the ink, thereby improving fixability between the sheet and the ink. The drying module 3000 includes a decoupling unit 3200, a drying belt unit 3300, and a warm air blowing unit 3400.

The sheet printed in the recording unit 2300 of the printing module 2000 is conveyed to the decoupling unit 3200 in the drying module 3000. The decoupling unit 3200 weakly holds and conveys the sheet by air pressure from above and belt friction.

This prevents displacement of the remaining portion of the sheet on the print belt unit 2200 under a state in which the sheet extends astride the decoupling unit 3200 and the print belt unit 2200.

The sheet conveyed from the decoupling unit 3200 is conveyed through suction to the drying belt unit 3300, and at the same time, hot air is blown to the sheet from the warm air blowing unit 3400 arranged above the belt to dry the ink application surface (image printed surface). In addition to the hot air blowing method, the drying method may include a combination of a method of irradiating the sheet surface with electromagnetic waves (such as ultraviolet rays and infrared rays) and a conduction heat transfer method through contact of heating elements.

The fixing module 4000 fixes the image on the sheet by heating the sheet dried in the drying module 3000 and by drying the ink. The fixing module 4000 includes a fixing belt unit 4100 including an upper belt unit 4110 and a lower belt unit 4120. The fixing module 4000 causes the sheet conveyed from the drying module 3000 to pass between the heated upper belt unit 4110 and lower belt unit 4120, and thus causes the ink solvent to fully permeate (fixes) the sheet.

The cooling module 5000 cools the sheet on which the image has been fixed by the fixing module 4000, and thus solidifies the ink softened by heating and suppresses a temperature change of the sheet caused by downstream devices. The cooling module 5000 includes a plurality of cooling units 5001. The plurality of cooling units 5001 cool the high-temperature sheet conveyed from the fixing module 4000. Each cooling unit 5001 is configured to cool a sheet by taking outside air into a cooling box with a fan to increase the pressure in the cooling box, and by exposing the sheet to air blown out from nozzles formed in a conveyance guide. The plurality of cooling units 5001 are arranged on both sides of the conveyance path, and hence can cool the sheet from both sides.

A conveyance path switching unit is provided in the cooling module 5000. The conveyance path switching unit switches conveyance paths for the sheet according to whether the sheet is conveyed to the reversing module 6000 or to a double-sided printing conveyance path to be used for double-sided printing.

During double-sided printing, the sheet is conveyed to the lower conveyance path in the cooling module 5000, and is conveyed through the double-sided printing conveyance paths of the fixing module 4000, the drying module 3000, the printing module 2000, and the sheet feeding module 1000. A double-sided printing conveyance unit of the fixing module 4000 is provided with a first reversing unit 4200 that reverses the front and back surfaces of the sheet. After the sheet is once conveyed to the first reversing unit 4200, the sheet is reversed and conveyed to the drying module 3000 side, and thus the printed surface with the image is reversed. Owing to conveyance of the sheet through the first reversing unit 4200, printing can be performed on the back surface of the sheet. The sheet is then conveyed again to the pre-image-forming registration correction unit, the print belt unit 2200, and the recording unit 2300 of the printing module 2000, and printing is performed on the sheet.

The reversing module 6000 includes a second reversing unit 6400. The reversing module 6000 can reverse, by the second reversing unit 6400, the front and back surfaces of the sheet to be conveyed. Thus, the orientation of the front and back surfaces of the sheet to be discharged can be changed. The sheet discharging and stacking module 7000 includes a top tray 7200 and a stacking unit 7500. The sheet discharging and stacking module 7000 aligns and stacks the sheets conveyed from the reversing module 6000 onto the top tray 7200 or the stacking unit 7500.

### <Arrangement of Circuit Boards>

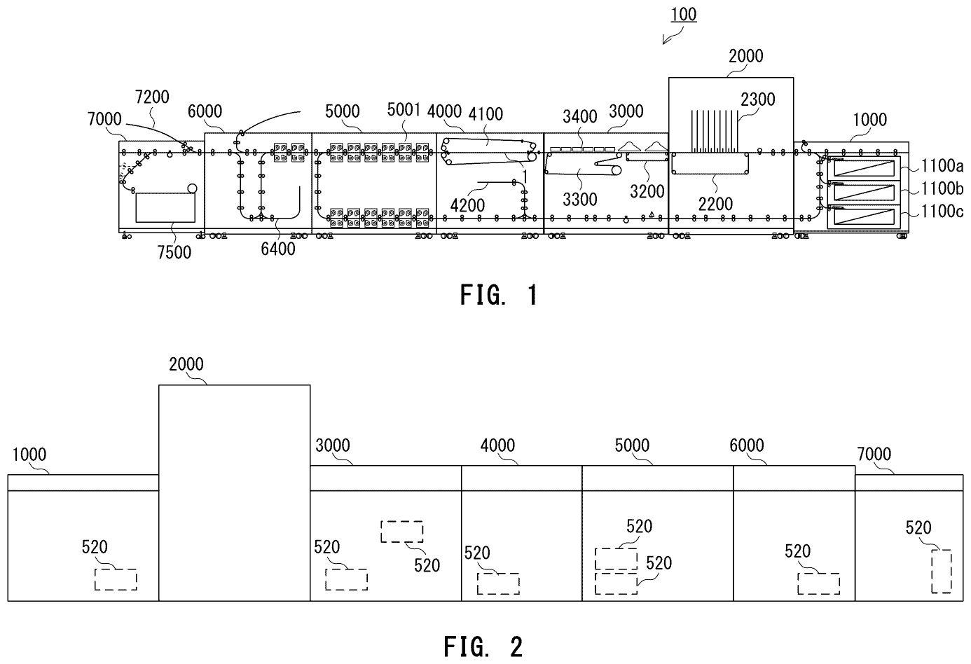

FIG. 2 is an explanatory view for illustrating an arrangement of electrical circuits mounted on the respective modules of the ink jet recording apparatus 100. Each of the electrical circuits includes a circuit board having an electronic component mounted thereon. FIG. 2 is a back view for illustrating the ink jet recording apparatus 100. The electrical circuit is used for, for example, a predetermined operation relating to image formation by each module. In FIG. 2, an arrangement of protection circuit boards 520 each having a protection circuit mounted thereon, which serve as an example of the circuit board included in the electrical circuit, is described. In general, the image forming apparatus is provided with a protection circuit for electrically protecting the electronic component mounted on the circuit board in case of input of an excessive voltage. The protection circuit is provided in the vicinity of a portion to which electrical power is input from the outside.

In a system including a plurality of modules as in the ink jet recording apparatus 100 according to this embodiment, the protection circuit boards 520 are provided for the respective modules. The protection circuit boards 520 are mounted on the back side of the respective modules. In the ink jet recording apparatus 100 according to this embodiment, eight protection circuit boards 520 in total are arranged in six modules out of the seven modules. Peripheral configurations of the protection circuit boards 520 of the respective modules are not the same, and are specific to the respective modules.

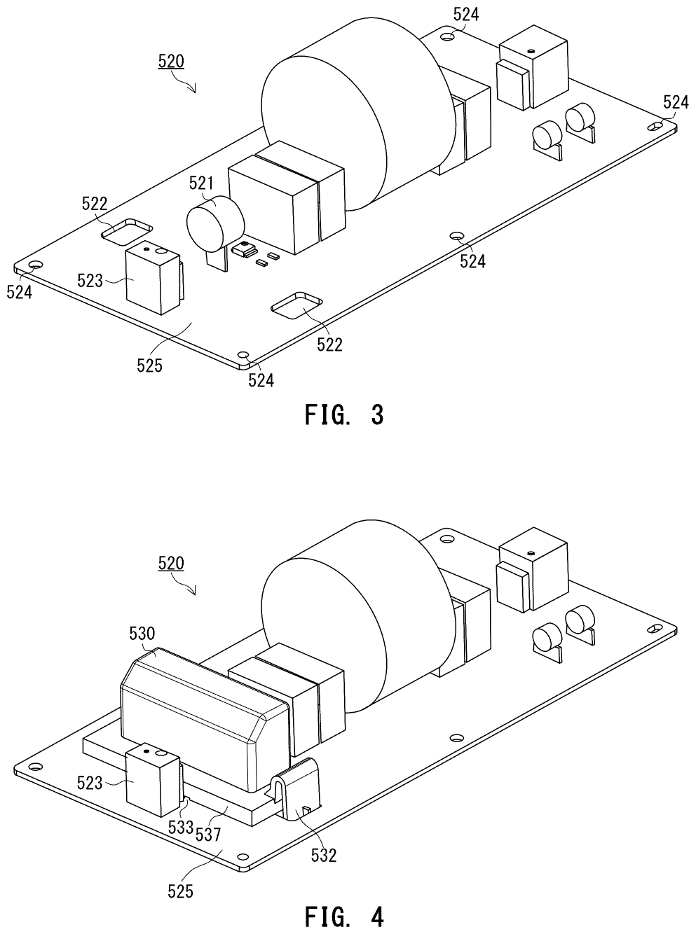

FIG. 3 is an explanatory view for illustrating a configuration of the protection circuit board 520. The protection circuit board 520 includes a varistor 521 which is a voltage-dependent resistor for electrically protecting other electronic components mounted on the protection circuit board 520 in a case where an excessive voltage is input. On a substrate surface 525, a connector 523 to which an input terminal from the outside is to be connected is provided so as to be opposed to the varistor 521. At positions on the right and the left of the varistor 521, cover mounting holes 522 for mounting an element cover to be described later are provided. A plurality of substrate mounting holes 524 are provided in edge portions of the protection circuit board 520. With the substrate mounting holes 524, the protection circuit board 520 is fixed by screws to a mounting support plate which is a metal plate component to be described later. The mounting support plate is mounted to a predetermined position of the module.

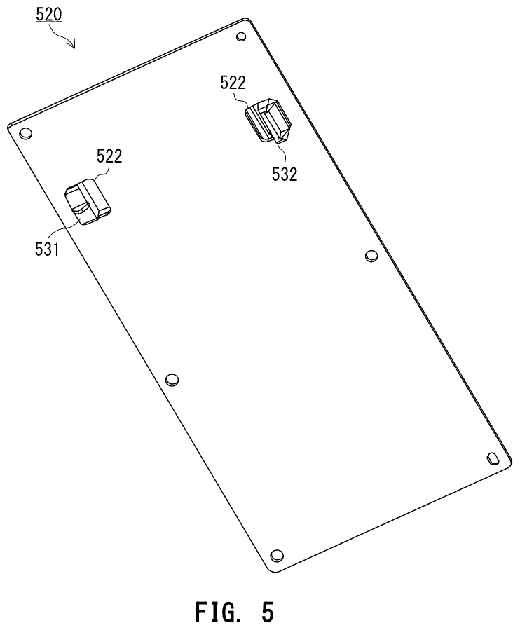

FIG. 4 and FIG. 5 are explanatory views for illustrating the configuration of the protection circuit board 520 in a state in which the element cover is mounted. FIG. 4 is a view for illustrating a state in which an element cover 530 is mounted as viewed from the mounting surface side (substrate surface 525, component surface side) of the protection circuit board 520, and FIG. 5 is a view as viewed from a solder surface thereof.

The element cover 530 is mounted so as to cover the varistor 521 on the protection circuit board 520. The element cover 530 includes a side wall 537 having a cutout portion 533, and the side wall 537 allows the element cover 530 to come into contact with the substrate surface 525. The element cover 530 includes an engaging portion 531 at one side and a flexible engaging portion 532 at another side. The engaging portion 531 is inserted through the cover mounting hole 522 of the protection circuit board 520 so as to engage with the solder surface of the protection circuit board 520.

The solder surface is an opposite surface to the substrate surface 525. The flexible engaging portion 532 has a flexible support portion and a claw provided at the end of the flexible support portion. The flexible engaging portion 532 deflects during the fixing prosses of the element cover 530 to the substrate surface 525. For example, when the engaging portion 531 is being inserted through the cover mounting hole 522, the flexible engaging portion 532 is not inserted through the cover mounting hole 522. After the engaging portion 531 engages with the solder surface, the flexible engaging portion 532 starts to be inserted into the mounting hole 522.

When the flexible engaging portion 532 is being inserted through the cover mounting hole 522, the flexible support portion of the flexible engaging portion 532 deflects so that the claw at the end can pass the mounting hole 522. After the claw at the end passes the mounting hole 522, the deflection of the flexible engaging portion 532 is released and the claw engages with the solder surface. In another way, the flexible engaging portion 532 is first inserted through the mounting hole 522 and engages with the substrate surface 525 while the engaging portion 531 is not inserted the mounting hole 522. Then the flexible engaging portion 532 deflects so that the engaging portion 531 can pass the mounting hole 522.

After releasing the deflection of the flexible engaging portion 532, the engaging portion 531 engages with the solder surface. By engagements of the engaging portion 531 and the flexible engaging portion 532 with the solder surface, the element cover 530 is fixed to the substrate surface 525, and is integrated with the protection circuit board 520.

With the element cover 530 being mounted, the varistor 521 projecting from the substrate surface 525 of the protection circuit board 520 is protected. That is, in a case where an operator removes the protection circuit board 520 or operates in the vicinity of the protection circuit board 520 for assembly work or maintenance work, the operator is prevented from erroneously coming into contact with the varistor 521. Accordingly, the varistor 521 is protected from being damaged.

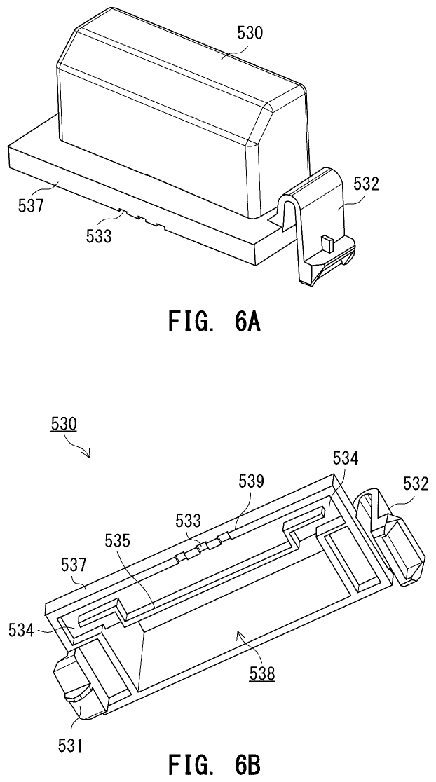

FIG. 6A and FIG. 6B are explanatory views for illustrating the configuration of the element cover 530. FIG. 6A is a perspective view for illustrating the element cover 530, and FIG. 6B is a view obtained by viewing FIG. 6A from below. The element cover 530 in this embodiment is made of a flame-retarded resin, and is formed by, for example, injection molding.

The element cover 530 includes the side wall 537 at an outer peripheral portion as described above. The side wall 537 is brought into contact with the substrate surface 525 of the protection circuit board 520 so that the element cover 530 incorporates the varistor 521 therein. The cutout portion 533 is provided in a part of the side wall 537. In a case where the side wall 537 is brought into contact with the substrate surface 525, an opening (gap) is formed between the cutout portion 533 and the substrate surface 525. With this opening, a path (communication path 534) of an air stream communicated from the outside to the inside of the element cover 530 is formed. Accordingly, heat generated by the varistor 521 inside the element cover 530 is discharged to the outside of the element cover 530 through the opening.

Hereinafter, the opening is described from another viewpoint. The side wall 537 in this embodiment includes a first part and a second part. The first part of the side wall 537 is a part in contact with the substrate surface 525. The second part of the side wall 537 is a part provided with the cutout portion 533. That is, the opening is formed between the second part of the side wall 537 and the substrate surface 525. Further, the side wall 537 includes an edge portion 539. At least a part of the edge portion 539 is brought into contact with the substrate surface 525. For the sake of convenience, the edge portion 539 includes a first edge portion corresponding to the first part of the side wall 537, and a second edge portion corresponding to the second part of the side wall 537. That is, the edge portion 539 of the side wall 537 includes the first edge portion to be brought into contact with the substrate surface 525, and the second edge portion not to be brought into contact with the substrate surface 525. In this case, the second edge portion is formed as the cutout portion 533 with respect to the first edge portion.

A varistor accommodating space 538 for incorporating the varistor 521 is formed inside the element cover 530. A shielding rib 535 is provided as a shielding member between the cutout portion 533 and the varistor 521 arranged in the varistor accommodating space 538. An end of the shielding rib 535 is brought into contact with the substrate surface 525 similarly to the side wall 537. With the shielding rib 535, the varistor accommodating space 538 and the cutout portion 533 are communicated with each other through communication paths 534 of two right and left systems, which are each bent in a crank shape. Through the shielding by the shielding rib 535, the varistor 521 provided inside the varistor accommodating space 538 is invisible directly from the cutout portion 533 (opening). That is, the communication paths 534 are formed so as to bypass the shielding rib 535. Conversely, the shielding rib 535 does not block the path of the air stream from the outside of the element cover 530 to the varistor accommodating space 538. As described above, the shielding rib 535 divides the varistor accommodating space 538 into a first space facing the opening and a second space in which the varistor 521 is arranged. Further, the shielding rib 535 branches the path communicated from the first space to the second space into branching paths of two systems.

The element cover 530 includes a top surface portion which is substantially parallel to the mounting surface (substrate surface 525). Each of the first part and the second part of the side wall 537 and the shielding rib 535 includes a plate portion which is continuous from the top surface portion and extends substantially perpendicular to the mounting surface.

As described above, the varistor accommodating space 538 and the cutout portion 533 are communicated with each other, and hence air is less liable to get stuffy in the varistor accommodating space 538, and the temperature rise of the varistor 521 can be suppressed. The size of the cutout portion 533 and the size of the communication path 534 are determined depending on the type of the electronic component accommodated inside the element cover 530.

The communication path 534 has a crank-shaped labyrinth structure, and hence the varistor accommodating space 538 has a configuration in which a foreign matter is less liable to enter the inside of the varistor accommodating space 538 from the cutout portion 533. Further, even when a foreign matter enters the varistor accommodating space 538, two systems of communication paths 534 are provided, and hence the possibility that the path between the cutout portion 533 and the varistor accommodating space 538 is completely closed is low. Further, at a position opposed to the cutout portion 533 (opening) on the outer side of the element cover 530, the connector 523 of the protection circuit board 520 is arranged. The connector 523 has a size equal to or larger than a projection area of the opening formed by the cutout portion 533 and the substrate surface 525. Accordingly, the connector 523 functions as a shielding object for hindering entrance of a foreign matter into the cutout portion 533. In this case, an example in which the connector 523 is provided as the shielding object is described, but the shielding object may be other electronic components.

The communication paths 534 and the cutout portion 533 can be formed by the draft direction of a mold used in injection molding. Accordingly, the height of the cutout portion 533 can be finely adjusted. The shielding rib 535 can also be easily processed, and hence the flexibility of the shape of the communication path 534 can be enhanced.

In this embodiment, description has been given of a configuration in which the opening is formed by the cutout portion 533 and the substrate surface 525. As a modification example, there may be employed a configuration in which the side wall 537 itself has an opening (hole) in place of the cutout portion 533. That is, an opening whose entire periphery is surrounded by the side wall 537 may be provided. In this case, it can be considered that, between the second part of the side wall 537 and the substrate surface 525, the opening and a third part which is another different part of the side wall 537 are arranged. Further, a plurality of openings may be provided. In any case, the element cover 530 is only required to have a configuration in which, under a state in which at least a part of the side wall 537 is brought into contact with the substrate surface 525, an opening which allows the varistor accommodating space 538 to be communicated with an external space is provided, and the electronic component provided inside the varistor accommodating space 538 is invisible from the external space.

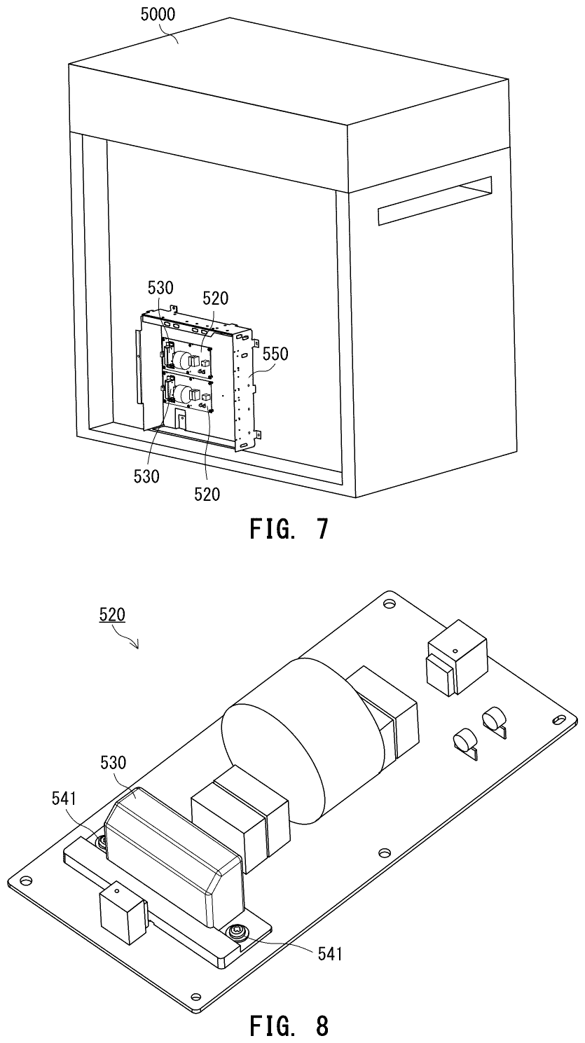

FIG. 7 is an explanatory view for illustrating a state in which the protection circuit board 520 is mounted to the cooling module 5000. As described above, the protection circuit board 520 is mounted on the back side of the cooling module 5000. FIG. 7 exemplifies a state in which a back side exterior cover of the cooling module 5000 is removed so that the protection circuit board 520 is exposed. Even when the protection circuit board 520 is mounted to other modules, similar configurations are taken.

The protection circuit board 520 is mounted to a mounting support plate 550 under a state in which the element cover 530 is mounted. In a case where the mounting support plate 550 is fixed to a frame member of the cooling module 5000, the protection circuit board 520 is mounted to the cooling module 5000. In the protection circuit board 520, the electronic component (varistor 521) is protected by the element cover 530, and hence it is not required to separately provide a protection cover or the like for protecting the entire protection circuit board 520. Accordingly, the protection circuit board 520 can be mounted directly below the exterior cover.

With such a configuration, the flexibility of the arrangement of the protection circuit board 520 is enhanced. Further, the number of components used in the protection circuit board 520 is reduced, and this configuration is also effective in terms of cost reduction. The electrical circuit according to this embodiment is completed with the configurations of the protection circuit board 520 and the element cover 530 on the circuit board, and hence is less affected by surrounding configurations. In this manner, even when a plurality of modules have different internal configurations as in the ink jet recording apparatus 100 according to this embodiment, the configuration of the electrical circuit formed of the protection circuit board 520 and the element cover 530 can be used in common.

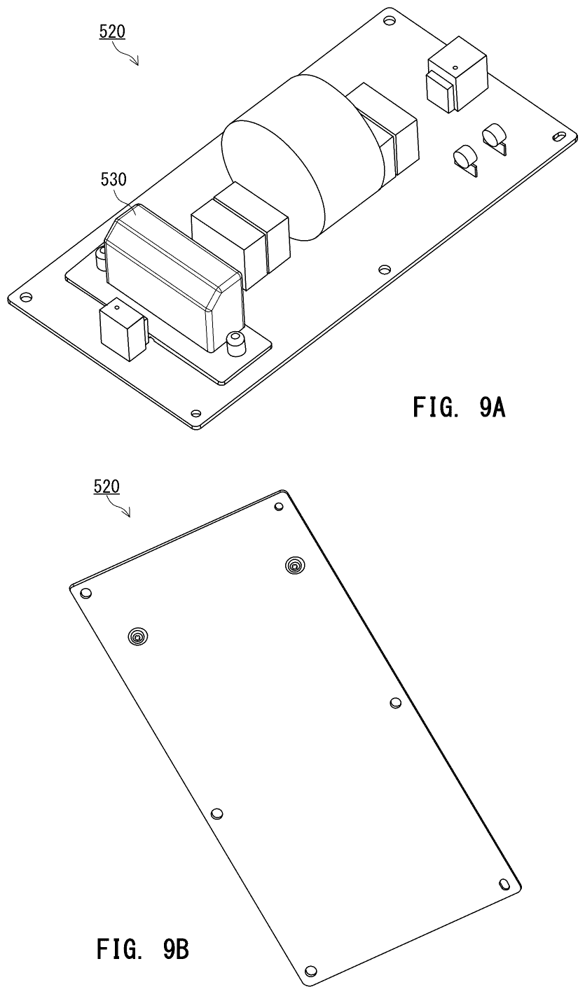

FIG. 8, FIG. 9A, and FIG. 9B are explanatory views for illustrating another examples of a method of fixing the element cover 530. In FIG. 8, the element cover 530 is fixed to the protection circuit board 520 by screws 541. In FIG. 8, screw fastening is performed from the substrate surface 525 side of the protection circuit board 520.

In FIG. 9A and FIG. 9B, the screw fastening is performed from the solder surface side of the protection circuit board 520. As illustrated in FIG. 9A, female threads are provided on the element cover 530 side, and, as illustrated in FIG. 9B, screw fastening is performed from the solder surface side (side of a surface opposite to the substrate surface 525).

As described above, in the electrical circuit according to this embodiment, the element cover 530 can protect the electronic component (varistor 521) mounted on the circuit board (protection circuit board 520) from being damaged. In a case where the element cover 530 is mounted on the protection circuit board 520, heat generated by the electronic component (varistor 521) is emitted from the opening provided in the element cover 530. In this manner, the temperature rise of the electronic component (varistor 521) can be suppressed. Further, another cover for covering the entire circuit board (protection circuit board 520) is not required, and hence a space required at the time of mounting the circuit board (protection circuit board 520) to the apparatus can be reduced as compared to the related art. Accordingly, in the electrical circuit according to this embodiment, while the life of the electronic component mounted on the circuit board is kept long, the electronic component can be protected from being damaged.

Description has been given above of the varistor 521 as an example of the electronic component to be protected by the element cover 530, but the electronic component serving as a protection target is not limited thereto, and any element mounted on the circuit board becomes the electronic component serving as the protection target. Further, the element cover 530 may be provided so as to cover a plurality of electronic components mounted on the circuit board. Further, a plurality of element covers 530 may be mounted on the circuit board.

The circuit board is also not limited to the protection circuit board 520, and the element cover 530 can be used as long as the circuit board is a circuit board capable of mounting an electronic component, such as a power supply board, a high-voltage board, or a control board. Further, description has been given above of a case of single-sided mounting in which electronic components are mounted on one surface of the circuit board, but, even in a case of double-sided mounting in which electronic components are mounted on both surfaces of the circuit board, the element cover 530 can be used on both the surfaces.

While the present disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of priority from Japanese Patent Application No. 2024-034645, filed Mar. 7, 2024, which is hereby incorporated by reference herein in its entirety.

What is claimed is:

1. An electrical circuit, comprising:
an electronic component;
a circuit board having a first surface on which the electronic component is arranged; and
a cover provided on the first surface and configured to form an accommodating space where the electronic component is accommodated, the cover including a first part and a second part,
wherein the first part of the cover is in contact with the first surface of the circuit board,
wherein an opening is formed between the second part of the cover and the first surface of the circuit board,
wherein a path of an air stream is formed, the path communicating from an outside of the cover to the electronic component in the accommodating space through the opening, and
wherein the cover includes a shielding member arranged between the opening and the electronic component in the accommodating space.

2. The electrical circuit according to claim 1,
wherein an edge of the cover includes a first edge portion corresponding to the first part and a second edge portion corresponding to the second part,
wherein the first edge portion is in contact with the first surface of the circuit board,
wherein the second edge portion is formed as a cutout portion with respect to the cover, and
wherein the opening is formed between the cutout portion and the first surface.

3. The electrical circuit according to claim 1, wherein the shielding member is arranged so that the electronic component is invisible through the opening.

4. The electrical circuit according to claim 1,
wherein the path is formed so as to bypass the shielding member so that the path is prevented from being blocked by the shielding member.

5. The electrical circuit according to claim 1,
wherein the cover includes a first engaging portion having a flexible support and an engaging claw provided at an end of the flexible support,
wherein the circuit board has a first mounting hole through which the flexible support is inserted, and
wherein the claw of the first engaging portion engages with a second surface of the circuit board opposite to the first surface.

6. The electrical circuit according to claim 5,
wherein the cover includes a second engaging portion,
wherein the circuit board has a second mounting hole through which the second engaging portion is inserted, and
wherein the first engaging portion and the second engaging portion respectively engage with a second surface of the circuit board opposite to the first surface

7. The electrical circuit according to claim 1,
wherein the cover includes a first engaging portion and a second engaging portion,
wherein the circuit board has a first mounting hole through which the first engaging portion is inserted and a second mounting hole through which the second engaging portion is inserted, and
wherein the first engaging portion and the second engaging portion respectively engage with a second surface of the circuit board opposite to the first surface.

8. The electrical circuit according to claim 1, wherein the shielding member divides the accommodating space into a first space facing the opening and a second space in which the electronic component is arranged.

9. The electrical circuit according to claim 8,
wherein the cover includes a top surface portion substantially parallel to the first surface of the circuit board,
wherein each of the first part, the second part, and the shielding member includes a plate portion which is continuous from the top surface portion and extends substantially perpendicular to the first surface of the circuit board, and
wherein an edge of the shielding member is in contact with the first surface of the circuit board.

10. The electrical circuit according to claim 8, wherein the shielding member is configured to branch the path into at least two branching paths each communicated from the first space to the second space.

11. The electrical circuit according to claim 10, wherein the shielding member has a labyrinth structure, and provides each of the at least two branching paths with a crank.

12. The electrical circuit according to claim 1, wherein, on the first surface of the circuit board, a shielding object is arranged outside the cover and at a position opposed to the opening.

13. The electrical circuit according to claim 12, wherein the shielding object has a size equal to or larger than a projection area of the opening.

14. The electrical circuit according to claim 13, wherein the shielding object includes a connector mounted on the circuit board.

15. The electrical circuit according to claim 1, wherein the cover is fixed to the circuit board by a screw.

16. The electrical circuit according to claim 1, wherein the electronic component includes a protection circuit configured to electrically protect other electronic component mounted on the circuit board.

17. The electrical circuit according to claim 1, wherein the electronic component includes a varistor.

18. An image forming apparatus, comprising:
a module configured to perform an operation relating to image formation; and
an electrical circuit configured to be used in the operation of the module,
wherein the electrical circuit includes:
an electronic component;
a circuit board having a first surface on which the electronic component is arranged; and
a cover provided on the first surface and configured to form an accommodating space where the electronic component is accommodated, the cover including a first part and a second part,
wherein the first part of the cover is in contact with the first surface of the circuit board,
wherein an opening is formed between the second part of the cover and the first surface of the circuit board,
wherein a path of an air stream is formed, the path communicating from an outside of the cover to the electronic component in the accommodating space through the opening, and
wherein the cover includes a shielding member arranged between the opening and the electronic component in the accommodating space.

19. The image forming apparatus according to claim 18, wherein the circuit board is a protection circuit board having a protection circuit mounted thereon to electrically protect other electronic component mounted on the circuit board.
